(19) United States
(12) Patent Application Publication
(10) Pub. No.: US 2006/0221584 A1
(43) Pub. Date: Oct. 5, 2006

(54) Method for ground noise suppression

(75) Inventors: Wen-Hsiung Huang, Taipei (TW); Kuo-Pin Lee, Taipei (TW)

Correspondence Address: FULBRIGHT AND JAWORSKI LLP, 555 S. FLOWER STREET, 41ST FLOOR, LOS ANGELES, CA, 90071, US

(73) Assignee: INVENTEC CORPORATION

(21) Appl. No.: 11/097,401

(22) Filed: Mar. 31, 2005

(51) Int. Cl. H05K 7/06

(52) U.S. Cl. 361/780; 361/782; 361/783

(57) ABSTRACT

A method for ground noise suppression is applied to a power loop of a circuit board by reducing the effects caused by electromagnetic interference (EMI). The power loop at least includes a switch driver and two or more passive components. The method of the present invention is to connect ground connecting pins of the passive components to a digital ground in an inner layer of the circuit board via a power ground in an outer layer of the circuit board, which is connected to a ground connecting pin of the switch driver connecting to the digital ground, restraining the loop path of the power loop. The connecting style of this power loop is used to actively implement more direct connections among the components in the power loop, thus preventing ground noise from radiating via different paths due to excessive loop path length. Therefore, the random distribution of power can be prevented and EMI interference to surrounding electronic components can be beneficially reduced.

### FIELD OF THE INVENTION

The present invention relates to a technique for ground noise suppression, and more particularly, to a method for ground noise suppression by altering ground connection between electronic components to improve electromagnetic interferences.

### DESCRIPTION OF THE PRIOR ART

Electronic products these days are getting more powerful in terms of functionality and performance. The layout of wiring traces of electronic/printed circuit boards is also getting more complex. In the past, noise and electromagnetic interference (EMI) was not a major cause of concern in the design of electronic circuit boards, but today, with the increase in complexity of designs, it is now a factor to be taken into account when designing the layout of electronic circuit boards. Electronic equipment most of time is under the influence of EMI. Potentially problematic EMI may originate from many sources such as power supplies, basic electronic components, and also from the usage of the equipment itself (self-induced EMI). Such electronic equipment may even be damaged by EMI; however, the occurrence of such incidents is not common. But on the other hand, EMI is well known to produce noticeable effects on electronic equipment in terms of performance. EMI may cause problems such as the temporary malfunctioning of electronic equipment, loss or alteration of stored data, and reduced reliability in terms of functionality. As a consequence, such electronic equipment may not function optimally. Thus, the electromagnetic interference presents a critical and urgent technical problem to be resolved.

Noise suppression measures and techniques to reduce the effects of EMI are already being implemented in the design of printed circuit board trace routing, and these issues are also being used as one measure of the performance of such a system. A filter circuit for suppressing ground noise on a circuit board that is commonly used today is shown in FIG. 1. Ground connecting pins 1a, 2a, and 3a of a switch driver 1, passive component 2, and passive component 3 respectively are connected directly to a digital ground 4 that is an inner layer of the circuit board. However, this method easily allows EMI to be radiated via different paths (as shown in FIG. 3), thus becoming a radiating interference source, which generates even more noise or interference, affecting the operation of other electronic components mounted on the board. This may result in an unexpectedly higher level of EMI being generated by the electronic product, sometimes leading to the design not being in conformance with regulations related to certification.

In accordance with the aforementioned limitation, the present invention proposes utilizing a circuit loop to effectively suppress noise and reduce EMI in order to solve this urgent technical need.

### SUMMARY OF THE INVENTION

In order to solve the problems of the prior art, a primary objective of the present invention is to provide a method for suppressing ground noise. The method of the present invention enables a more direct connection among components in a power loop path. The more direct connection restrains the loop path length, hence preventing the ground noise and decreasing EMI (Electro Magnetic Interference) to surrounding components.

In order to achieve the above objectives, a method for ground noise suppression is proposed by the present invention.

The method for ground noise suppression of the present invention is applied in a filter circuit. The filter circuit is provided on a circuit board, and it includes a switch driver (e.g. a bidirectional controllable silicon switch driver) and a plurality of passive components (e.g. bypass capacitors). The method electrically couples the ground connecting pins of the passive components to a digital ground via a power ground in the outer layer of the circuit board connecting to a ground connecting pin of a switch driver connected to the digital ground. This serves to forcibly restrain the loop path of the power loop, effectively avoiding currents running randomly in order to reduce the generation of ground noise, and it also suppresses radiation generated by electric fields and unintentional frequency signals that could cause interference to the surrounding components. The designed electronic circuit will have a higher ability to conform to the requirements set for obtaining certification by international certification bodies.

### BRIEF DESCRIPTION OF THE DRAWINGS

A better understanding of the present invention can be obtained when the forgoing detailed description is considered in conjunction with the following drawings, in which:

FIG. 1 is a cross-sectional view showing the ground connection of components in a conventional power loop.

FIG. 2 is a cross-sectional view illustrating a power loop of the applied method of the present invention and ground connection of components in the loop.

FIG. 3 is a schematic diagram showing the circuit structure in the conventional power loop in FIG. 1.

FIG. 4 is a schematic diagram showing the circuit structure in the power loop of the present invention in FIG. 2.

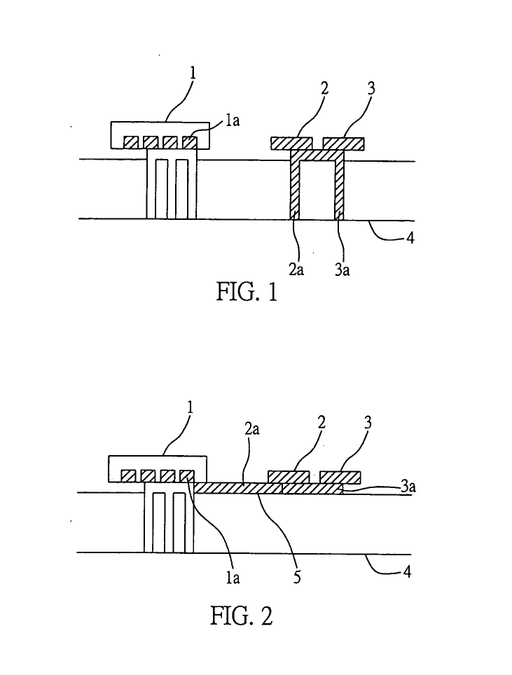

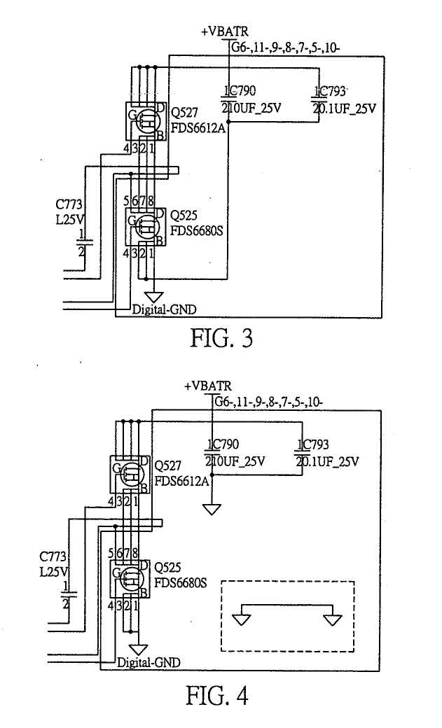

### DETAILED DESCRIPTION OF THE PREFFERED EMBODIMENT

The descriptions below of specific embodiments illustrate the present invention. Others skilled in the art can easily understand other advantages and features of the present invention from the contents disclosed in this specification. The present invention can be carried out or applied through different embodiments. The details of this specification can be modified based on different viewpoints and applications yet still fall within the scope of the present invention.

Only the components of interest in the design are shown in the diagrams to emphasize the unique features of this invention and also to keep the diagrams clear and simple.

FIG. 2 is a cross-sectional view illustrating a power loop of the applied method of the present invention and ground connection of components in the loop. In the following embodiments, the method of the present invention is applied to a power loop contained in a filter circuit on a circuit board for reducing ground noise and decreasing the effects caused by EMI on surrounding electronic components. As shown in the diagram, the components in the power loop include at least a switch driver 1 (e.g. a bidirectional controllable silicon switch driver), a passive component 2 (e.g. a bypass capacitor) and a passive component 3 (e.g. a bypass capacitor), wherein the switch driver 1 is used to drive a bidirectional controllable silicon switch with a large power rating. The switch driver 1 can be selected to provide three types of peak isolation voltages (e.g. 250V, 400V or 600V) and three trigger currents (e.g. 5 A, 10 A or 15 Å). Passive component 2 and passive component 3 are a tantalum/electrolytic capacitor and a 0.1 uF ceramic capacitor, respectively, and these are connected together in parallel. These capacitors are used to remove unneeded common mode filter energy from components or cables, which helps eliminate excessive energy and stabilize the electromagnetic compatibility of the circuit.

As shown in FIG. 2, ground pins 2a and 3a of the passive components 2 and 3, respectively, are connected to the ground pin 1a of the switch driver 1 via a power ground 5 in the outer layer of the circuit board. Hence, the ground pins 2a and 3a can be connected to the digital ground 4 in the inner layer of the circuit board via the ground pin 1a. Therefore, the connections among the components in the power loop can be made more direct (as shown in FIG. 4). This forcibly restrains the loop path of the power loop, which effectively prevents power from scattering randomly, helping to reduce the generation of ground noise, as well as suppressing radiation generated by electric fields, thereby reducing undesirable frequency signals that might cause interference. Consequently, the effects of EMI on the surrounding components will then be reduced, thus improving the circuit performance so as to be certified by the international standards.

In accordance with the aforementioned design, bypass capacitor 2 and bypass capacitor 3 shown in FIG. 2 are connected to the ground pin 1a through the power ground 5 of the outer layer of the circuit board. Hence, bypass capacitors 2 and 3 can also be connected to the digital ground 4 in the inner layer of the circuit board via the ground pin 1a. The connecting style of this power loop is used to actively implement more direct connections among the components in the power loop, thus preventing ground noise from radiating via different paths due to excessive loop path length. This can suppress radiation caused by electric fields emitted by signals and generation of undesired frequency signals. Hence this effectively prevents power from being scattered randomly, reducing the effects caused by EMI to surrounding components. With such an improvement, the designed electronic circuit can have higher performance in terms of speed or reliability, and will have a higher chance of passing certification standards of the various internationally standards bodies.

The embodiment described above is only to illustrate aspects of the present invention; it should not be construed as intending to limit the scope of the present invention in any way.

While the invention has been described in detail with reference to a specific embodiment thereof, it will be apparent in the art that various changes and modifications can be made, and equivalents employed, without departing from the scope of the invention as described in the following claims.

What is claimed is:

1. A method for ground noise suppression applicable to a power loop provided on a circuit board, the power loop comprising a switch driver and a plurality of passive components, wherein the phenomenon of components in the power loop being affected by electromagnetic interference can be reduced by reducing generation of ground noise by coupling ground connecting pins of the passive components to a digital ground in the circuit board via a power ground in the circuit board connecting to a ground connecting pin of the switch driver connected to the digital ground, in order to restrain the loop path of the power loop.

2. The method as claimed in claim 1, wherein the switch driver is a bidirectional controllable silicon switch driver.

3. The method as claimed in claim 2, wherein the bidirectional controllable silicon switch driver provides a peak blocking voltage that is one selected from the group consisting of 250V, 400V and 600V.

4. The method as claimed in claim 2, wherein the bidirectional controllable silicon switch driver provides a trigger current that is one selected from the group consisting of 5 A, 10 A and 15 A.

5. The method as claimed in claim 1, wherein the passive components are bypass capacitors.

6. The method as claimed in claim 5, wherein the bypass capacitors comprise a tantalum/electrolytic capacitor connected in parallel with a 0.1 uF ceramic capacitor.

7. The method as claimed in claim 1, wherein the power ground is in the outer layer of the circuit board.

8. The method as claimed in claim 1, wherein the digital ground is in the inner layer of the circuit board.
